(19) United States
(12) Patent Application Publication
(10) Pub. No.: US 2025/0185354 A1
(43) Pub. Date: Jun. 5, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chuan-Cheng Tsou, Hsinchu (TW); Tsung-Jing Wu, Hsinchu (TW); Sung-Hsin Yang, Hsinchu (TW); Jung-Chi Jeng, Hsinchu (TW); Chen-Chieh CHIANG, Hsinchu (TW); Ling-Sung WANG, Hsinchu (TW)

(73) Assignee: Taiwan Semiconductor Manufacturing Company, Ltd., Hsinchu (TW)

(21) Appl. No.: 18/526,177

(22) Filed: Dec. 1, 2023

(51) Int. Cl. H01L 27/088; H01L 21/8234

(52) U.S. Cl. CPC H10D 84/834; H10D 84/0144; H10D 84/0158; H10D 84/038

(57) ABSTRACT

A semiconductor device and a manufacturing method thereof are provided. The semiconductor device includes a substrate, a plurality of fin structures, a gate oxide layer and a gate electrode layer. The fin structures are disposed on the substrate. The gate oxide layer is formed on the fin structures. The gate electrode layer covers the gate oxide layer and is substantially perpendicular to the fin structures, wherein the fin structures include a first type of fin and a second type of fin, and the gate oxide layer includes a first gate oxide portion and a second gate oxide portion, the first gate oxide portion covers the first type of fin, and the second gate oxide portion covers the second type of fin.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

Recently, multi-gate devices have been introduced into fin field-effect transistors (FinFETs). FinFETs have been used in various applications, for example, to implement logic devices/circuits and to provide static random-access memory (SRAM) devices or the like. Generally speaking, logic devices may focus on electrical performance (e.g., threshold voltage, saturation current, and breakdown voltage etc.), while SRAM devices may focus on optimizing the size of memory cells and improving operating voltages of memory cells and other requirements. However, optimization of the performance and/or design requirements of FinFET devices has been challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device according to an embodiment of the disclosure.

FIGS. 2A to 2H are schematic diagrams of a method of manufacturing the semiconductor device of FIG. 1.

FIG. 3 is a schematic diagram of a semiconductor device according to another embodiment of the disclosure.

FIGS. 4A to 4E are schematic diagrams of a method of manufacturing the semiconductor device of FIG. 3.

FIG. 5 is a schematic diagram of a semiconductor device according to another embodiment of the disclosure.

FIGS. 6A to 6E are schematic diagrams of a method of manufacturing the semiconductor device of FIG. 5.

FIG. 7 is a schematic three-dimensional view of a FinFET device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

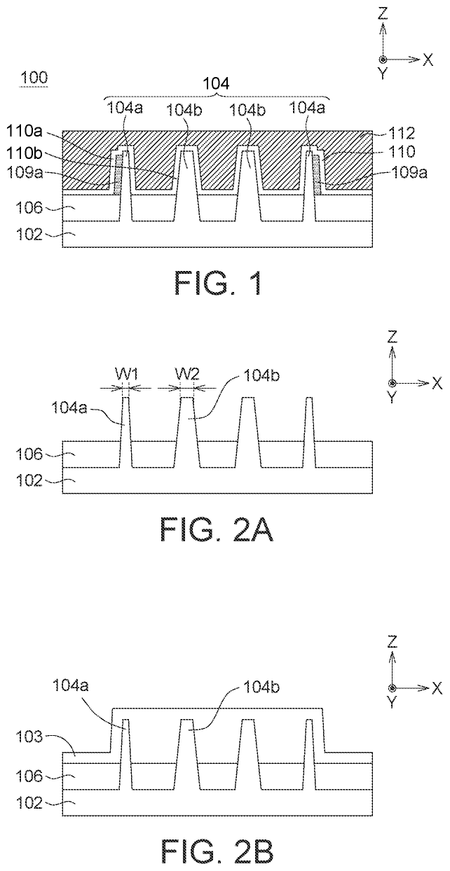

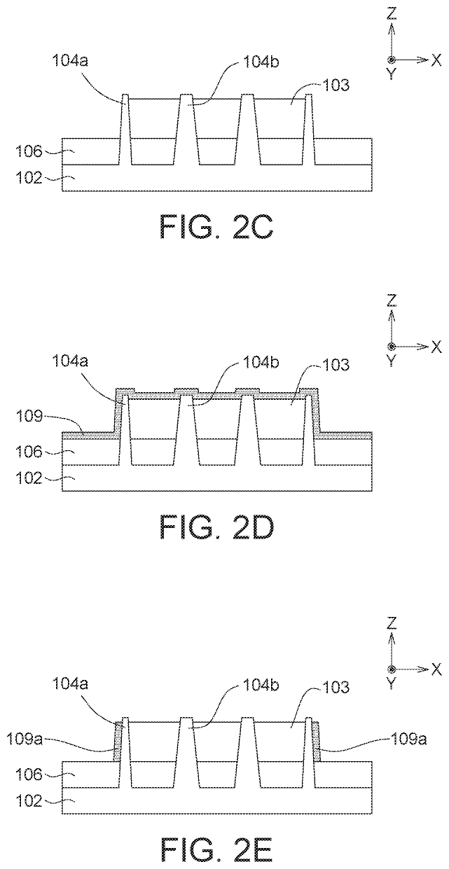

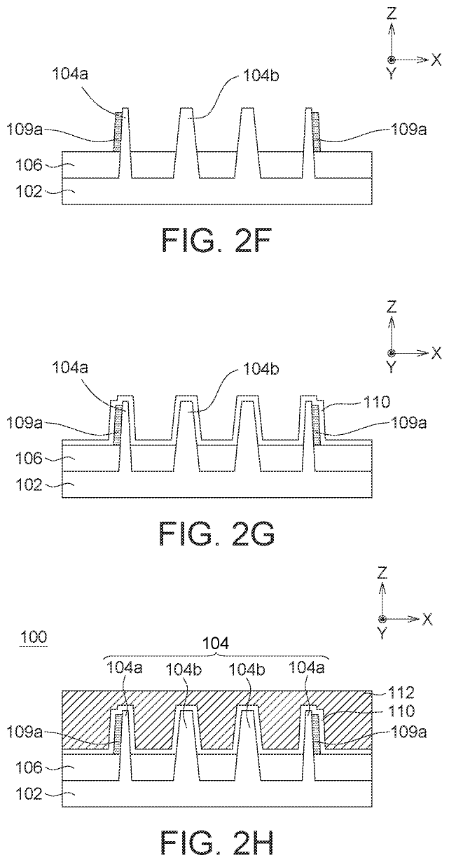

Referring to FIG. 1, a schematic diagram of a semiconductor device 100 according to an embodiment of the present disclosure is provided. In FIG. 1, the semiconductor device 100 includes a substrate 102, a plurality of fin structures 104, a gate oxide layer 110 and a gate electrode layer 112. The fin structures 104 are disposed on the substrate 102. The gate oxide layer 110 is formed on the fin structures 104. The gate electrode layer 112 covers the gate oxide layer 110 and is substantially perpendicular to the fin structures 104. The fin structures 104 include a first type of fin and a second type of fin. The oxide layer 110 includes a first oxide portion 110a covering the first type of fin and a second oxide portion 110b covering the second type of fin. The method of manufacturing the semiconductor device 100 is described with reference to FIGS. 2A to 2H.

The semiconductor device 100 of this embodiment can be applied in a fin-based transistor structure, which includes three-dimensional fin structures 104 extending on the semiconductor substrate 102. The fin-based transistor structure is such as fin field effect transistors (FinFETs) or nanostructure transistors (such as nanowire transistors, nanosheet transistors, gate-all-around (GAA) transistors, multi-bridge channel transistors and nanoribbon transistors). The gate structure 108 surrounds the fin structures 104 of semiconductor material and is configured to control the flow of charge carriers within the channel region.

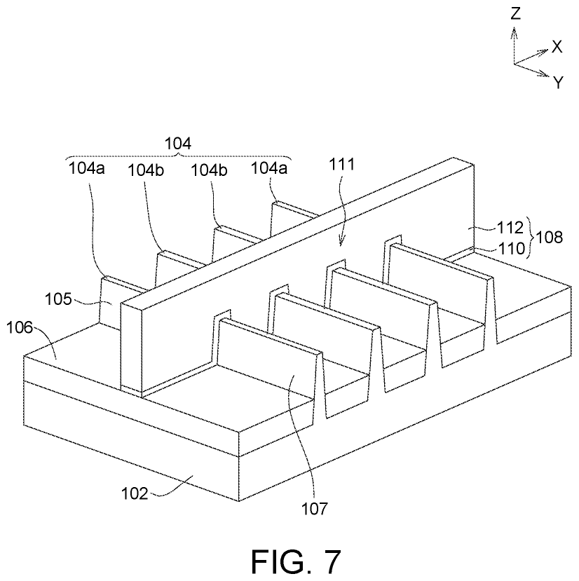

For example, in the FinFET device of FIG. 7, the gate structure 108 surrounds three sides of each fin structures 104 (and channel region 111), allowing increased control of channel region 111. The gate structure 108 includes a gate electrode layer 112 and a gate oxide layer 110. The gate electrode layer 112 overlaps the gate oxide layer 110. The gate structure 108 is formed between the source region 105 and the drain region 107 and is located above the channel region 111. The gate oxide layer 110 may include a dielectric material, such as a silicon oxide layer (SiO₂) or silicon oxynitride (SiON). The gate oxide layer 110 may include a high-K dielectric layer such as HfO₂, TiO₂, HfZrO, Ta₂O₃, HfSiO₄, ZrO₂, ZrSiO₂, combinations thereof, or other suitable materials. In some embodiments, the gate oxide layer 110 may be formed by chemical oxidation, thermal oxidation, atomic layer deposition (ALD), chemical vapor deposition (CVD), and/or other suitable methods. The gate electrode layer 112 may include a polysilicon layer or other suitable layer. For example, the gate electrode layer 112 may be formed by chemical vapor deposition (CVD), atomic layer deposition (ALD), LPCVD, PECVD, and/or other suitable deposition processes.

The gate electrode layer 112 may include a first group of metal materials for N-type FinFET and a second group of metal materials for P-type FinFET. Therefore, FinFET devices may include dual work-function metal gate configurations.

The FinFET devices have become popular candidates for high performance and low leakage applications (e.g., for logic devices and/or circuits). In various examples, FinFET devices employ narrow fin width for short channel control, improved current on/off ratio (Ion/off ratio), and continuously changing gate length. In addition, FinFET devices with multiple fins have been used in high-speed applications, but such devices still suffer from issues such as increased leakage and power consumption. In some embodiments, a single-fin FinFET device may be used to mitigate leakage and power dissipation issues, but this may also result in a reduction in the speed of the FinFET device. The semiconductor device 100 of the present disclosure can alleviate the current leakage and power consumption problems of FinFET devices with multiple fins, and can also avoid the reduction of the speed of FinFET devices.

The substrate 102 includes a silicon substrate, a substrate formed of a material including silicon, a substrate formed of a III-V compound semiconductor material, a silicon-on-insulator (SOI) substrate, germanium (Ge) substrate, silicon germanium (SiGe) substrate, or other types of semiconductor substrates. The above-mentioned III-V compound semiconductor material is, for example, gallium arsenide (GaAs).

As an example, the fin structures 104 may be formed by etching away a portion of the substrate 102 to form a groove in the substrate 102. The trenches may then be filled with the etched-back isolation material to form shallow trench isolation (STI) regions 106 on the substrate 102 and between the fin structures 104. Other manufacturing techniques for STI region 106, and/or for fin structures 104 may be used. The STI region 106 may electrically isolate adjacent active regions in the fin structures 104. The STI region 106 may include dielectric materials, such as silicon oxide (SiOx), silicon nitride (SiₓN_{y}), silicon oxynitride (SiON), and fused silica glass (FSG). low-k dielectric materials, and/or other suitable insulating materials. STI region 106 may include a multi-layer structure, such as one or more liners.

In some embodiments, the STI region 106 is formed to a height less than or equal to the height of the fin structures 104. In some embodiments, the planarization apparatus performs a planarization (or polishing) operation to planarize the STI region 106 such that the top surface of the STI region 106 is substantially flat and smooth, and such that the top surface of the STI region 106 and the top surfaces of the fin structures 104 are approximately at the same height. The planarization operation may increase the uniformity of the STI region 106 formed in a subsequent etch back operation.

The STI region 106 is etched in an etch-back operation to expose a portion of the fin structures 104. In one embodiment, a portion of STI region 106 may be etched using plasma etching techniques, wet chemical etching techniques, and/or other types of etching techniques.

The fin structures 104 may include silicon or other elemental semiconductors (e.g., germanium) or compound semiconductors. The compound semiconductors include silicon carbide, gallium arsenide, gallium phosphide, indium phosphide, indium arsenide and/or indium antimonide. Alloy semiconductors include SiGe, GaAsP, AlInAs, AlGaAs, InGaAs, GaInP and/or GaInAsP, or combinations thereof. The fin structures 104 may be fabricated using suitable processes including photolithography and etching processes. The lithography process may include forming a photoresist layer covering the substrate 102, exposing the photoresist layer to form a pattern by performing a post-exposure bake process, and using the photoresist layer to form a masking element. In addition, the fin structures 104 can be formed by a multiple patterning process, such as a double patterning lithography (DPL) process (for example, lithography-etch-lithography-etch (LELE) process, self-aligned double patterning (SADP) process, spacer-is-dielectric (SID) SADP process), triple patterning process (for example, lithography-etch-lithography-etch-lithography-etch (LELELE) process, self-aligned triple patterning (SATP) process), self-aligned quadruple patterning (SAQP) process, or a combination thereof. The etching process includes dry etching, wet etching and/or other suitable methods. Other embodiments (such as maskless lithography or nanoimprint technology) may also be used for the exposure process.

In one embodiment, the fin structures 104 include a first type of fin (also referred to as edge fins 104a) and a second type of fin (also referred to as center fins 104b) disposed on the substrate 102. The number of fins is greater than or equal to 3. The fin structures 104 extend substantially parallel to each other along a first direction (e.g., Y direction) and a third direction (e.g., Z direction), and each fin structures 104 has a length defined in the first direction (e.g., Y direction), a width defined in the second direction (e.g., X direction), and a height defined in the third direction (e.g., Z direction). This disclosure considers changes in the height, width, and/or length of the fin structures 104 that may result from etching process and manufacturing precision. For example, in FIG. 1, the width of the fin structures 104 changes from the upper portion of each fin to the lower portion of each fin. In the depicted embodiment, the width tapers from the lower portion of the fin to the upper portion of the fin such that the average width of the upper portion is less than the average width of the lower portion. In some embodiments, the width along the fin structures 104 may vary from about 3 nm to about 20 nm, depending on where the width of the fin structures 104 is measured. In some embodiments, the width of the fin structures 104 varies depending on the position of the fins relative to each other and/or the position of the fin structures 104 relative to other portions of the semiconductor device 100. For example, the width W2 of the center fin 104b may be greater than the width W1 of the edge fin 104a. In another embodiment, the center fin 104b may alternatively have a smaller width than the edge fin 104a. In both embodiments, the width W1 of edge fin 104a may represent the average width of edge fin 104a, and the width W2 of center fin 104b may represent the average width of center fin 104b.

For example, the difference between the average width of the center fin 104b and the average width of the edge fin 104a may be from about 3 nm to about 10 nm. As shown in FIG. 7, each fin has at least one channel region 111, at least one source region 105 and at least one drain region 107 defined along its length in the first direction (e.g., Y direction), the channel region 111 is disposed between the source region 105 and the drain region 107 (commonly referred to as source/drain regions 105, 107). The channel region 111 includes a top defined between two sidewall portions, where the top and sidewall portions engage the gate electrode layer 112 such that the current can flow between the source/drain regions 105, 107 during operation.

The gate structure 108 extends along a second direction (e.g., X direction) and is substantially perpendicular to the extension direction of the fin structures 104. The gate structure 108 is disposed above the channel region 111 of each fin so as to be inserted between the source/drain regions 105, 107 of each fin such that the current can flow between the source/drain regions 105, 107 during operation.

In one embodiment, in order to prevent the edge fin 104a with a smaller width from breaking or cracking, a reinforcing member 109a is formed on the sidewall portion of the edge fin 104a. The height of the reinforcing member 109a can be less than or equal to the height of the top of the fin structures 104, and the reinforcing member 109a extends along a first direction (e.g., Y direction) and is substantially parallel to the extension direction of the fin structures 104. In one embodiment, the width of the reinforcing member 109a is greater than 2 nm, such as between about 3 nm and about 10 nm, and the height of the reinforcing member 109a is between about 50 nm and about 100 nm.

In some embodiments, the reinforcing member 109a includes two reinforcing members 109a respectively formed on the sidewall portions of the two outermost edge fins 104a of the fin structures 104. The reinforcing member 109a may be a silicon-containing oxide, carbide, oxynitride, or metal oxide. silicon-containing oxides, carbides and oxynitrides include silicon oxide (SiOx), silicon carbide (SiC), silicon oxynitride (SiON) or silicon oxycarbon (SiOC). The metal oxide is, for example, a high-K dielectric layer, such as HfO₂, TiO₂, HfZrO, Ta₂O₃, HfSiO₄, ZrO₂, ZrSiO₂, combinations thereof, or other suitable materials. In some embodiments, reinforcing member 109a may be formed by chemical oxidation, thermal oxidation, atomic layer deposition (ALD), chemical vapor deposition (CVD), and/or other suitable methods.

Referring to FIGS. 2A to 2H, a schematic diagram of a method of manufacturing the semiconductor device 100 of FIG. 1 is provided. In one embodiment, The method of manufacturing the semiconductor device 100 includes forming a plurality of fin structures 104 on a substrate 102 and forming a STI region 106 on the substrate 102 and between the fin structures 104. The manufacturing method of the fin structures 104 and the STI region 106 has been described in detail above and does not repeat here. Next, a mask layer 103 is formed on the substrate 102 to cover the fin structures 104. The mask layer 103 is, for example, a photoresist layer or plasma enhanced oxide (PEOX). A part of the photoresist layer can be removed through processes such as exposure and development, so that the remaining photoresist layer covers the top of the fin structures 104. As shown in FIG. 2C, the sidewall portions of the two outermost edge fins 104a of the fin structures 104 are exposed outside the mask layer 103. Next, as shown in FIG. 2D, a protective layer 109 is formed on the fin structures 104. The protective layer 109 conforms to the fin structures 104 and the mask layer 103 and fully covers the tops of the fin structures 104 and the mask layer 103 and the sidewall portions of edge fin 104a. Next, a horizontal portion of the protective layer 109 is selectively removed and the vertical portion is retained by etching process. For example, the protective layer 109 is subjected to anisotropic etching, plasma etching, wet chemical etching and/or other types of etching, so that the sidewall portions of the two outermost edge fins 104a of the fin structures 104 is formed with a reinforcing member 109a to strengthen the structure of the edge fins 104a. Next, as shown in FIG. 2F, the mask layer 103 is removed to expose the fin structures 104. As shown in FIG. 2G, a gate oxide layer 110 is formed on the fin structures 104 and the reinforcing member 109a. As shown in FIG. 2H, a gate electrode layer 112 is formed on the gate oxide layer 110, and the gate oxide layer 110 is isolated between the gate electrode layer 112 and the fin structures 104. In one embodiment, the reinforcing member 109a may be made of the same or different material as the gate oxide layer 110. The reinforcing member 109a can increase the thickness of the gate oxide layer 110 corresponding to covering the first type of fin (edge fin 104a) to increase the breakdown voltage of the dielectric layer.

In one embodiment, the reinforcing member 109a can be used as a sidewall structure of the edge fin 104a to improve the reliability problem of insufficient width of the edge fin 104a, and can also solve the problem of the time-dependent dielectric breakdown (TDDB) at the edge fin 104a due to insufficient thickness of the dielectric layer.

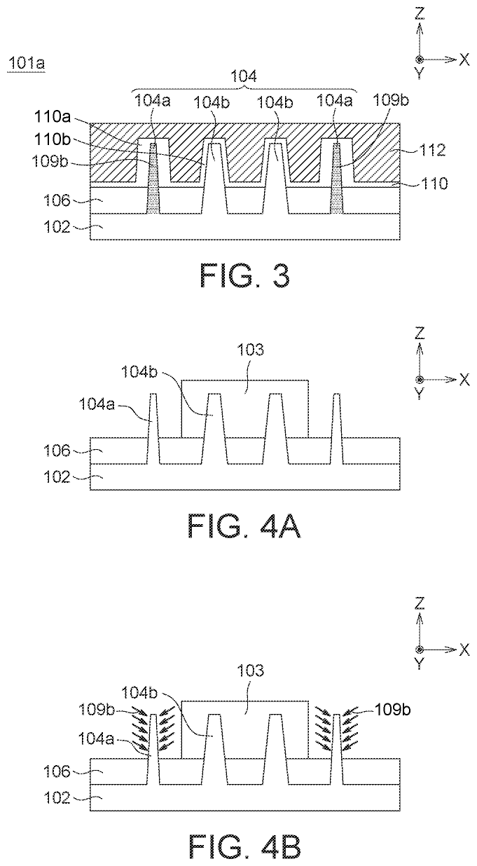

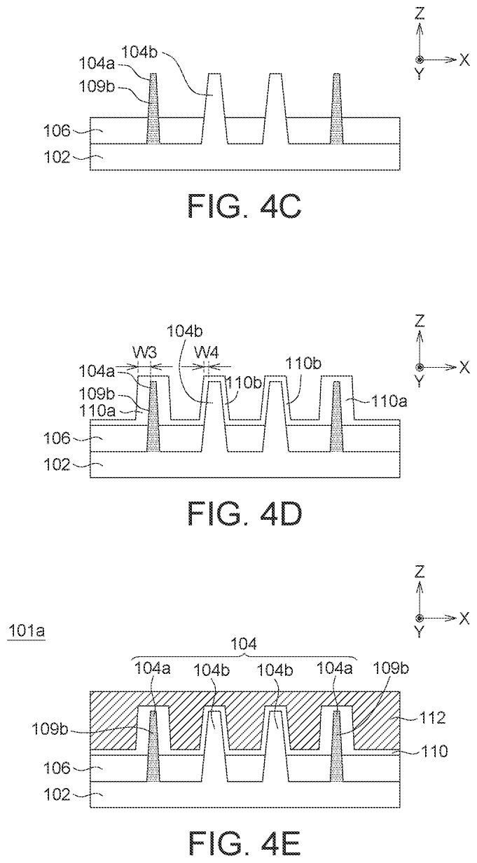

Referring to FIG. 3, a schematic diagram of a semiconductor device 101a according to another embodiment of the present disclosure is provided. In FIG. 3, the semiconductor device 101a includes a substrate 102, a plurality of fin structures 104, a gate oxide layer 110 and a gate electrode layer 112. The fin structures 104 are disposed on the substrate 102. The gate oxide layer 110 is formed on the fin structures 104. The gate electrode layer 112 covers the gate oxide layer 110 and is substantially perpendicular to the fin structures 104, wherein the fin structures 104 include a first type of fin and a second type of fin. The oxide layer 110 includes a first oxide portion 110a covering the first type of fin and a second oxide portion 110b covering the second type of fin. The method of manufacturing the semiconductor device 101a is described with reference to FIGS. 4A to 4E.

The difference between this embodiment and the above-mentioned embodiment is that: the first type of fin is at least one edge fin 104a that has been processed by fluorine implantation, and the second type of fin is at least one center fin 104b that has not been processed by fluorine implantation. The fluorine implantation process is, for example, implanting fluorine ions 109b into the edge fins 104a. The edge fins 104a are located on both sides of the center fins 104b, and the width W2 of the center fins 104b may be greater than the width W1 of the edge fins 104a, for example, the difference between the average width of the center fins 104b and the average width of the edge fins 104a may range from about 3 nm to about 10 nm.

In one embodiment, as the fin structures 104 scale to deep sub-micron size, the reliability of the ultra-thin gate oxide layer 110 becomes increasingly important. Doping an appropriate amount of fluorine ions 109b in the edge fin 104a helps to improve the characteristics of the gate oxide layer 110. When the fluorine ions 109b diffuses into the gate oxide layer 110 to form a Si—F bond, because the bonding energy of Si—F is relatively large, it is not easy to break the Si—F bond when the gate oxide layer 110 is applied by high current and high electric field, so that the breakdown voltage of the gate oxide layer 110 can be increased. In addition, a thicker first oxide portion 110a can be formed on the edge fins 104a that have been processed by fluorine implantation, and a second oxide portion 110b thinner than the first oxide portion 110a can be formed on the center fins 104b that has not been processed by fluorine implantation. Since the thickness of the first oxide portion 110a is greater than the thickness of the second oxide portion 110b, the problem of the time-dependnet dielectric breakdown (TDDB) at the edge fins 104a due to insufficient thickness of the dielectric layer can be solved.

Referring to FIGS. 4A to 4E, a schematic diagram of a method of manufacturing the semiconductor device 101a of FIG. 3 is provided. In one embodiment, a method of manufacturing the semiconductor device 101a includes forming a plurality of fin structures 104 on a substrate 102, and forming a STI region 106 on the substrate 102 and between the fin structures 104. The manufacturing method of the fin structures 104 and the STI region 106 has been described in detail above and does not repeat here. Next, a mask layer 103 is formed on the substrate 102. The mask layer 103 covers the center fins 104b, but does not cover the edge fins 104a. superior. The mask layer 103 is, for example, a photoresist layer. The photoresist layer can remove a part of the photoresist layer through processes such as exposure and development, so that the remaining photoresist layer correspondingly covers the center fins 104b. Next, as shown in FIG. 4B, the edge fins 104a are subjected to a fluorine implantation process, and the fluorine ions 109b are implanted in the edge fins 104a. The center fins 104b does not undergo fluorine implantation. Next, as shown in FIG. 4C, the mask layer 103 is removed to expose the center fins 104b. As shown in FIG. 4D, a gate oxide layer 110 is formed on the fin structures 104. As shown in FIG. 4E, a gate electrode layer 112 is formed on the gate oxide layer 110, and the gate oxide layer 110 is isolated between the gate electrode layer 112 and the fin structures 104. In one embodiment, a Si—F bond is formed in the first oxide portion 110a of the gate oxide layer 110 to improve the bonding strength, and the thickness W3 of the first oxide portion 110a of the gate oxide layer 110 may be greater than the thickness W4 of the second oxide portion 110b of the gate oxide layer 110 to improve the reliability problem of insufficient width of the edge fins 104a, and can also solve the problem of the time-dependnet dielectric breakdown (TDDB) at the edge fins 104a due to insufficient thickness of the dielectric layer.

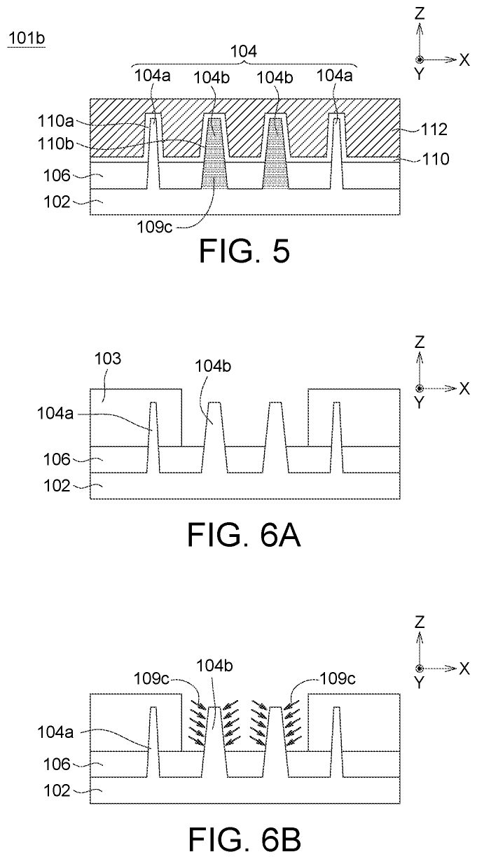

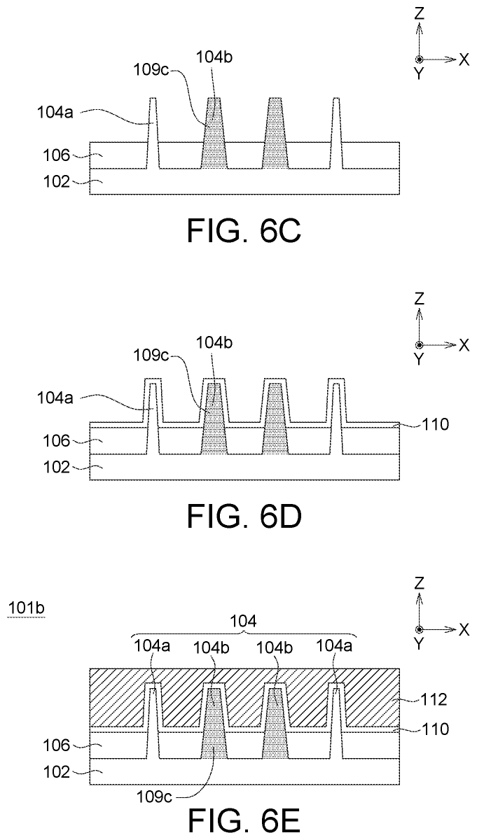

Referring to FIG. 5, a schematic diagram of a semiconductor device 101b according to another embodiment of the present disclosure is provided. In FIG. 5, the semiconductor device 101b includes a substrate 102, a plurality of fin structures 104, a gate oxide layer 110 and a gate electrode layer 112. The fin structures 104 are disposed on the substrate 102. The gate oxide layer 110 is formed on the fin structures 104. The gate electrode layer 112 covers the gate oxide layer 110 and is substantially perpendicular to the fin structures 104. The fin structures 104 include a first type of fin and a second type of fin. The oxide layer 110 includes a first oxide portion 110a covering the first type of fin and a second oxide portion 110b covering the second type of fin. The method of manufacturing the semiconductor device 101b is described with reference to FIGS. 6A to 6E.

The difference between this embodiment and the above embodiment is that: the first type of fin is at least one edge fin 104a that has not been processed by oxide implantation, and the second type of fin is at least one center fin 104b that has been processed by oxide implantation. The oxide implantation process is, for example, implanting the oxide 109c in the center fins 104b. The edge fins 104a are located on both sides of the center fins 104b, and the width W2 of the center fin 104b may be greater than the width W1 of the edge fins 104a, for example, the difference between the average width of the center fins 104b and the average width of the edge fins 104a may range from about 3 nm to about 10 nm.

In one embodiment, as the fin structures 104 scale to deep sub-micron size, the reliability of the ultra-thin gate oxide layer 110 becomes increasingly important. An appropriate amount of implanted oxide 109c in the center fins 104b is helpful to increase the etching rate of the subsequent etching process and thereby reduce the etching time, the edge fin 104a is prevented from being damaged in the subsequent etching process. The etching process may include, for example, a dummy spacer removal process on the dummy spacer of the semiconductor device 101b and/or a dummy gate dielectric layer removal process on the dummy gate dielectric layer of the semiconductor device 101b. In addition, during the dummy gate removal process, the dummy gate dielectric layer formed between the dummy gate and the fin structures 104 can be used as an etch stop layer. The materials of the dummy spacer and the dummy gate dielectric layer can be a dielectric material, such as silicon nitride, silicon oxynitride, silicon carbide, silicon oxide or a combination thereof.

Referring to FIGS. 6A to 6E, a schematic diagram of a method of manufacturing the semiconductor device 101b of FIG. 5 is provided. In one embodiment, a method of manufacturing the semiconductor device 101b includes forming a plurality of fin structures 104 on a substrate 102, and forming a STI region 106 on the substrate 102 and between the fin structures 104. The manufacturing method of the fin structures 104 and the STI region 106 has been described in detail above and does not repeat here. Next, a mask layer 103 is formed on the substrate 102. The mask layer 103 covers the edge fins 104a but does not cover the center fins 104b. The mask layer 103 is, for example, a photoresist layer. The photoresist layer can remove a part of the photoresist layer through processes such as exposure and development, so that the remaining photoresist layer correspondingly covers the edge fins 104a. Next, as shown in FIG. 6B, an oxide implantation process is performed on the center fins 104b, and the oxide 109c is implanted in the center fins 104b, so that the center fins 104b contain silicon and oxide 109c. The edge fins 104a do not undergo oxide implantation, so that the edge fins 104a contain silicon but does not contain oxide 109c. Next, as shown in FIG. 6C, the mask layer 103 is removed. As shown in FIG. 6D, a gate oxide layer 110 is formed on the fin structures 104. As shown in FIG. 6E, a gate electrode layer 112 is formed on the gate oxide layer 110, and the gate oxide layer 110 is isolated between the gate electrode layer 112 and the fin structures 104. In one embodiment, the thickness of the first oxide portion 110a and the thickness of the second oxide portion 110b of the gate oxide layer 110 can be maintained consistent or different. In addition, due to the increased etching rate and reduced etching time, even if the width of the edge fins 104a is insufficient, damage to the edge fins 104a can be avoided through the above process, and the fin structures 104 of the present disclosure can be applied to the semiconductor device 101b with lower operating voltage and operating current to maintain the reliability of the semiconductor device 100.

Referring to FIG. 7, a three-dimensional schematic diagram of a FinFET device (also referred to as a semiconductor device 100) is provided. The fin structures 104 are disposed on the substrate 102, and the gate electrode layer 112 covers the fin structures 104 and is substantially perpendicular to the fin structures 104. Each fin structure 104 includes a source region 105 and a drain region 107 formed within, over, and/or around the fin structures 104. The source/drain regions 105, 107 may be epitaxially grown on fin structures 104. The channel region 111 of the transistor is disposed within the fin structures 104 and below the gate structure 108 along a plane substantially parallel to the Y direction. In some examples, channel region 111 of fin structures 104 includes a high mobility material, such as germanium, as well as any of the compound or alloy semiconductors discussed above and/or combinations thereof. High mobility materials include those with electron mobilities greater than silicon. For example, in some cases, high mobility materials have an intrinsic electron mobility greater than about 1350 cm²/V-s and a hole mobility greater than about 480 cm²/V-s above room temperature (300K).

In addition, before forming the source/drain contacts over the source region 105 and/or the drain region 107, a metal silicide layer may be formed on the top surface of the source/drain regions 105, 107 to reduce contact resistance between the source/drain regions 105, 107 and the source/drain contacts. A pre-clean process may be used to prepare the top surfaces of source/drain regions 105, 107 for metal silicide to remove remaining oxides and other contaminants. After the pre-cleaning process, a metal layer is formed over the source/drain regions 105 and 107, and a high-temperature annealing is performed targeting the wafer. The high-temperature annealing causes the metal to react with silicon to form a metal silicide layer.

In some embodiments, the fin structures 104 has, for example, three or more fins, and the number of fins may represent the number of channels of the transistor. In some embodiments, the number of fins in the source region 105 and the drain region 107 is equal to or different from the number of fins in the channel region 111. When the number or height of edge fins 104a is reduced, the number or width of channels will also be reduced. Therefore, reducing the number of edge fins 104a and/or reducing the height of the edge fins 104a can control the current through the channel region 111 to reduce power consumption.

In addition, in some embodiments, reinforcing members 109a are formed on the sidewalls of the two outermost edge fins 104a of the fin structures 104, and/or the fluorine ions 109b are implanted in the edge fins 104a, which can improve the breakdown voltage of the gate oxide layer 110 and avoid the problem of dielectric breakdown. In another embodiment, implanting the oxide 109c in the center fins 104b is helpful to increase the etching rate of the subsequent etching process and thereby reduce the etching time, and can prevent the edge fins 104a from being damaged in the subsequent etching process. The above examples may be combined together in a single embodiment or implemented separately.

The present disclosure relates to a semiconductor device and a manufacturing method thereof, in which the edge fins modified by reinforcing members can obtain stronger structure than traditional fin and gate oxide structure to improve reliability of time-dependnet dielectric breakdown (TDDB) and breakdown voltage (Vbd). In addition, flourine implantation on the edge fins with thinner fin size can obtain thicker gate oxide layer than that on the center fin, while oxide implantation on center fins can decrease etching time to avoid damage of the edge fins.

According to some embodiments of the present disclosure, a semiconductor device includes a substrate, a plurality of fin structures, a gate oxide layer and a gate electrode layer. The fin structures are disposed on the substrate. The gate oxide layer is formed on the fin structures. The gate electrode layer covers the gate oxide layer and is substantially perpendicular to the fin structures, wherein the fin structures include a first type of fin and a second type of fin, and the gate oxide layer includes a first oxide portion and a second oxide portion, the first oxide portion covers the first type of fin, and the second oxide portion covers the second type of fin.

According to some embodiments of the present disclosure, a method of manufacturing a semiconductor device is provided. A plurality of fin structures is formed on a substrate. A mask layer is formed on the substrate, and the mask layer covers the fin structures. a protective layer is formed on the fin structures so that a reinforcing member is formed on the side wall portion of at least one edge fin of the fin structures. The mask layer is removed to expose the fin structures. A gate oxide layer is formed on the fin structures and the reinforcing member. A gate electrode layer is formed on the gate oxide layer, and the gate oxide layer is isolated between the gate electrode layer and the fin structures.

According to some embodiments of the present disclosure, a method of manufacturing a semiconductor device is provided. A plurality of fin structures is formed on a substrate, wherein the fin structures include at least one edge fin and at least one center fin. A mask layer is formed on the substrate, and the mask layer covers the edge fin or the center fin. a modification process is performed on the edge fin or the center fin that is not covered by the mask layer. The mask layer is removed to expose the edge fin or the center fin. A gate structure is formed on the edge fin and the center fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a plurality of fin structures disposed on the substrate;
a gate oxide layer formed on the fin structures; and
a gate electrode layer covering the gate oxide layer and being substantially perpendicular to the fin structures, wherein the fin structures include a first type of fin and a second type of fin, and the gate oxide layer includes a first oxide portion covering the first type of fin, and a second oxide portion covering the second type of fin.

2. The semiconductor device according to claim 1, wherein the first type of fin comprises at least one edge fin, the second type of fin comprises at least one center fin, and the edge fin has a width smaller than a width of the center fin.

3. The semiconductor device according to claim 2, wherein a difference between the width of the center fin and the width of the edge fin is between 3 nm and 10 nm.

4. The semiconductor device according to claim 2, wherein the first type of fin includes a reinforcing member disposed on a sidewall portion of the edge fin.

5. The semiconductor device according to claim 4, wherein the reinforcing member has a height less than or equal to a height of a top of the edge fin.

6. The semiconductor device according to claim 4, wherein a material of the reinforcing member comprises oxide, carbide, oxynitride or metal oxide.

7. The semiconductor device according to claim 1, wherein the first type of fin comprises at least one edge fin that has been processed by fluorine implantation, and the second type of fin comprises at least one center fin that has not been processed by fluorine implantation, the edge fin has a width smaller than a width of the center fin.

8. The semiconductor device according to claim 7, wherein the first oxide portion has a width greater than a width of the second oxide portion.

9. The semiconductor device according to claim 1, wherein the first type of fin comprises at least one edge fin that has not been processed by oxide implantation, and the second type of fins comprises at least one center fin that has been processed by oxide implantation, and the edge fin has a width smaller than a width of the center fin.

10. The semiconductor device according to claim 9, wherein the center fin comprises silicon and oxide, and the edge fin comprises silicon.

11. A method of manufacturing a semiconductor device, comprising:
forming a plurality of fin structures on a substrate;
forming a mask layer on the substrate, and the mask layer covering the fin structures;
forming a protective layer on the fin structures so that a reinforcing member is formed on a sidewall portion of at least one edge fin of the fin structures;
removing the mask layer to expose the fin structures;
forming a gate oxide layer on the fin structures and the reinforcing member; and
forming a gate electrode layer on the gate oxide layer, and the gate oxide layer is isolated between the gate electrode layer and the fin structures.

12. The method according according to claim 11, wherein a material of the reinforcing member comprises oxide, carbide, nitrogen oxide or metal oxide.

13. The method according to claim 11, wherein the mask layer is a photoresist layer or a plasma enhanced oxide.

14. The method according to claim 11, wherein a width of the reinforcing member is greater than 2 nm.

15. A method of manufacturing a semiconductor device, comprising:
forming a plurality of fin structures on a substrate, wherein the fin structures comprise at least one edge fin and at least one center fin;
forming a mask layer on the substrate, and the mask layer covering the edge fin or the center fin;
performing a modification process on the edge fin or the center fin that is not covered by the mask layer;
removing the mask layer to expose the edge fin or the center fin; and
forming a gate structure on the edge fin and the center fin.

16. The method according to claim 15, wherein the modification process comprises performing a fluorine implantation on the edge fin.

17. The method according to claim 15, wherein the modifying process comprises performing an oxide implantation on the center fin.

18. The method according to claim 15, wherein the modifying process comprises forming a reinforcing member on a sidewall portion of the edge fin.

19. The method according to claim 18, wherein a material of the reinforcing member comprises oxide, carbide, nitrogen oxide or metal oxide.

20. The method according to claim 15, wherein the edge fin has a width smaller than a width of the center fin.
